(19) United States
(12) Patent Application Publication
(10) Pub. No.: US 2026/0040706 A1
(43) Pub. Date: Feb. 5, 2026

(54) LOW ENERGY PHOTON DETECTION WITH CMOS IMAGERS

(71) Applicant: SEMICONDUCTOR COMPONENTS INDUSTRIES, LLC, Scottsdale, AZ (US)

(72) Inventors: Jon DALEY, Boise, ID (US); Swarnal BORTHAKUR, Boise, ID (US); Kevin Lloyd BEAMAN, Boise, ID (US)

(73) Assignee: SEMICONDUCTOR COMPONENTS INDUSTRIES, LLC, Scottsdale, AZ (US)

(21) Appl. No.: 18/791,299

(22) Filed: Jul. 31, 2024

(51) Int. Cl. H01L 27/146; H04N 25/10; H04N 25/76

(52) U.S. Cl. CPC H10F 39/806; H04N 25/10; H04N 25/76; H10F 39/182; H10F 39/805; H10F 39/8063

(57) ABSTRACT

Image sensor, imaging systems, and methods for imaging low energy photons. The image sensor includes an upconversion layer, an energy emitter, and a plurality of silicon photodetectors. The upconversion layer is configured to emit visible light in response to infrared light when electrons in the upconversion layer are charged to a metastable state. The energy emitter is configured to charge the electrons in the upconversion layer to the metastable state. The plurality of silicon photodetectors are positioned behind the upconversion layer and configured to detect the visible light emitted by the upconversion layer.

### BACKGROUND

Image sensors are used in electronic devices such as cellular telephones, cameras, and computers to capture images. In particular, an electronic device is provided with an array of pixels arranged in a grid pattern. Each pixel receives incident photons, such as light, and converts the photons into electrical signals. Column circuitry is coupled to each column for reading out sensor signals from each pixel.

Low energy photons, such as short wave infrared (SWIR) light and near infrared (NIR) light, may be used for imaging in low light situations. For example, an image sensor may capture images of a scene by detecting passive infrared radiation emitted by objects in the scene. Further, infrared light may be emitted to illuminate a dark scene without distracting people in and around the scene.

### SUMMARY

Imaging of low energy photons with complementary metal-oxide semiconductor (CMOS) image sensors is difficult due to the low absorption rates of silicon photodetectors for low energy photons. Thus, the present disclosure provides CMOS image sensors, CMOS imaging systems, and methods for imaging low energy photons that, among other things, convert low energy photons to high energy photons that are detectable with silicon photodetectors.

The present disclosure provides an image sensor including, in one implementation, an upconversion layer, an energy emitter, and a plurality of silicon photodetectors. The upconversion layer is configured to emit visible light in response to infrared light when electrons in the upconversion layer are charged to a metastable state. The energy emitter is configured to charge the electrons in the upconversion layer to the metastable state. The plurality of silicon photodetectors are positioned behind the upconversion layer and configured to detect the visible light emitted by the upconversion layer.

The present disclosure also provides an imaging system including, in one implementation, an upconversion layer, a controller, and a complementary metal-oxide semiconductor (CMOS) image sensor. The upconversion layer is configured to emit visible light in response to infrared light when electrons in the upconversion layer are charged to a metastable state. The controller is configured to charge the electrons in the upconversion layer to the metastable state. The CMOS image sensor is configured to detect the visible light emitted by the upconversion layer.

The present disclosure further provides a method for imaging low energy photons. The method includes charging electrons in an upconversion layer to a metastable state. The method also includes emitting visible light with the upconversion layer in response to infrared light. The method further provides detecting the visible light emitted by the upconversion layer with a CMOS image sensor.

### BRIEF DESCRIPTION OF THE DRAWINGS

For a detailed description of example implementations, reference will now be made to the accompanying drawings in which:

FIG. 1A is a block diagram of an example of an imaging system in accordance with some implementations;

FIG. 1B is a diagram of an example of an imaging system incorporated in a vehicle in accordance with some implementations;

FIG. 2 is a partial schematic and a partial block diagram of an example of a complementary metal-oxide semiconductor (CMOS) image sensor in accordance with some implementations;

FIG. 3 is a schematic of an example of circuitry in one of the pixels included in the CMOS image sensor of FIG. 2 in accordance with some implementations;

FIG. 4 is a cross-sectional side view of an example of an upconversion layer for short wave infrared (SWIR) light that is positioned in front of an array of silicon photodetectors in accordance with some implementations;

FIGS. 5A and 5B are energy diagrams of examples of conversions from low energy photons to high energy photons with an upconversion layer for SWIR light in accordance with some implementations;

FIG. 6A is a cross-sectional side view of an example of microlenses positioned in front of an upconversion layer in accordance with some implementations;

FIG. 6B is a cross-sectional side view of an example of microlenses positioned behind an upconversion layer in accordance with some implementations;

FIG. 7 is a cross-sectional side view of an example of a low-pass light filter positioned in front of an upconversion layer in accordance with some implementations;

FIG. 8 is a cross-sectional side view of an example of a band-pass light filter positioned between an upconversion layer and an array of silicon photodetectors in accordance with some implementations;

FIG. 9 is a cross-sectional side view of an example of a cooling layer positioned behind an array of silicon photodetectors in accordance with some implementations;

FIG. 10 is a cross-sectional side view of an example of pyramid trenches included in silicon photodetectors in accordance with some implementations;

FIG. 11 is of a cross-sectional side view of an example of an upconversion layer for near infrared (NIR) light that is positioned in front of an array of silicon photodetectors in accordance with some implementations;

FIG. 12 is of a cross-sectional side view of examples of color filters that filter visible light emitted by different upconversion layers in accordance with some implementations; and

FIG. 13 is a flow diagram of an example of a method for imaging low energy photons in accordance with some implementations.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

Terms defining an elevation, such as “above”, “below”, “upper”, and “lower” shall be locational terms in reference to a direction of light incident upon a pixel array and/or an image pixel. Light entering shall be considered to interact with or pass objects and/or structures that are “above” and “upper” before interacting with or passing objects and/or structures that are “below” or “lower.” Thus, the locational terms may not have any relationship to the direction of the force of gravity.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate the fact the recited referent may be plural.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operational amplifier.

“Short wave infrared light” or “SWIR light” shall mean light with wavelengths ranging from about 1,000 and 1,700 nanometers (nm). “Near infrared light” or “NIR light” shall mean light with wavelengths ranging from about 750 and 1,000 nm. “Low energy photons” shall mean light with wavelengths greater than 700 nm. “High energy photons” shall mean visible light with wavelengths ranging from about 380 and 750 nm.

“Controller” shall mean, alone or in combination, individual circuit components, an application specific integrated circuit (ASIC), one or more microcontrollers with controlling software, a reduced-instruction-set computer (RISC) with controlling software, a digital signal processor (DSP), one or more processors with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various implementations of the invention. Although one or more of these implementations may be preferred, the implementations disclosed should not be interpreted, or otherwise used, as limiting the scope of the present disclosure, including the claims. In addition, one skilled in the art will understand that the following description has broad application, and the discussion of any implementation is meant only to be exemplary of that implementation, and not intended to intimate that the scope of the present disclosure, including the claims, is limited to that implementation.

Various examples are directed to complementary metal-oxide semiconductor (CMOS) image sensors and methods for imaging low energy photons. More particularly, at least some examples are directed to CMOS image sensors with an upconversion layer that converts low energy photons to high energy photons. More particularly still, at least some examples are directed to methods of charging electrons in an upconversion layer to a metastable state such that the upconversion layer emits low energy photons in response to infrared light. The specification now turns to an example system to orient the reader.

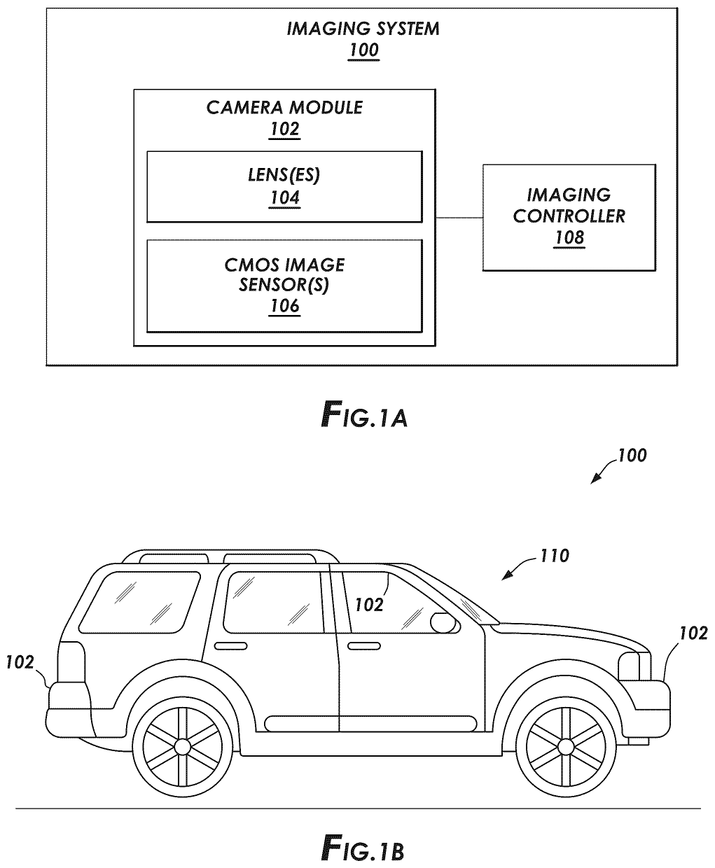

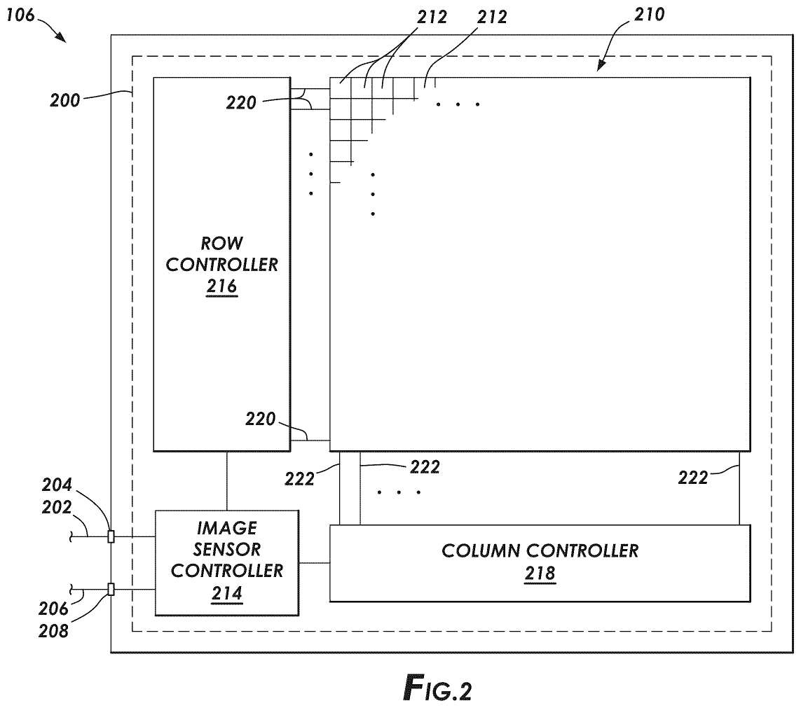

FIG. 1A shows an example of an imaging system 100. In particular, the imaging system 100 may be a portable electronic device such as a camera, a cellular telephone, a tablet computer, a webcam, a video camera, a video surveillance system, or a video gaming system with imaging capabilities. In other cases, the imaging system 100 may be an automotive imaging system. The imaging system 100 illustrated in FIG. 1A includes a camera module 102 that may be used to convert incoming light into digital image data. The camera module 102 may include one or more lenses 104 and one or more corresponding CMOS image sensors 106. The lenses 104 may include fixed and/or adjustable lenses. During image capture operations, light from a scene may be focused onto the CMOS image sensor 106 by the lenses 104. The CMOS image sensor 106 may comprise circuitry for converting analog pixel data into corresponding digital image data to be provided to the imaging controller 108. If desired, the camera module 102 may be provided with an array of lenses 104 and an array of corresponding CMOS image sensors 106.

The imaging controller 108 may include one or more integrated circuits. The imaging circuits may include image processing circuits, microprocessors, and storage devices, such as random-access memory, and non-volatile memory. The imaging controller 108 may be implemented using components that are separate from the camera module 102 and/or that form part of the camera module 102, for example, circuits that form part of the CMOS image sensor 106. Digital image data captured by the camera module 102 may be processed and stored using the imaging controller 108. Processed image data may, if desired, be provided to external equipment, such as computer, external display, or other device, using wired and/or wireless communications paths coupled to the imaging controller 108.

FIG. 1B shows another example of the imaging system 100. The imaging system 100 illustrated in FIG. 1B comprises an automobile or vehicle 110. The vehicle 110 is illustratively shown as a passenger vehicle, but the imaging system 100 may be other types of vehicles, including commercial vehicles, on-road vehicles, and off-road vehicles. Commercial vehicles may include busses and tractor-trailer vehicles. Off-road vehicles may include tractors and crop harvesting equipment. In the example of FIG. 1B, the vehicle 110 includes a forward-looking cameral module 102 arranged to capture images of scenes in front of the vehicle 110. Such a forward-looking camera module 102 can be used for any suitable purpose, such as lane-keeping assist, collision warning systems, distance-pacing cruise-control systems, autonomous driving systems, and proximity detection. The vehicle 110 further comprises a backward-looking camera module 102 arranged to capture images of scenes behind the vehicle 110. Such a backward-looking camera module 102 can be used for any suitable purpose, such as collision warning systems, reverse direction video, autonomous driving systems, proximity detection, monitoring position of overtaking vehicles, and backing up. The vehicle 110 further comprises a side-looking camera module 102 arranged to capture images of scenes beside the vehicle 110. Such a side-looking camera module 102 can be used for any suitable purpose, such as blind-spot monitoring, collision warning systems, autonomous driving systems, monitoring position of overtaking vehicles, lane-change detection, and proximity detection. In situations in which the imaging system 100 is a vehicle, the imaging controller 108 may be a controller of the vehicle 110. The discussion now turns in greater detail to the CMOS image sensor 106 of the camera module 102.

FIG. 2 shows an example of the CMOS image sensor 106. In particular, FIG. 2 shows that the CMOS image sensor 106 may comprise a silicon substrate 200 encapsulated within packaging to create a packaged semiconductor device or packaged semiconductor product. Bond pads or other connection points of the silicon substrate 200 couple to terminals of the CMOS image sensor 106. The connections may comprise a serial communication channel 202 coupled to a first terminal 204, and a capture input 206 coupled to a second terminal 208. Additional terminals will be present, such as ground, common, or power, but the additional terminals are omitted so as not to unduly complicate the figure. While a single instance of the silicon substrate 200 is shown, in other implementations, multiple substrates may be combined to form the CMOS image sensor 106 in a multi-chip module created before or after singulation.

The CMOS image sensor 106 illustrated in FIG. 2 includes a pixel array 210 with a plurality of pixels, such as pixels 212. The pixel array 210 may include, for example, hundreds or thousands of rows and columns of pixels 212. Control and readout of the pixel array 210 may be implemented by an image sensor controller 214 coupled to a row controller 216 and a column controller 218. The row controller 216 may receive row addresses from the image sensor controller 214 and supply corresponding row control signals to pixels 212, such as reset, row select, charge transfer, and readout control signals. The row control signals may be communicated over one or more conductors, such as row control paths 220.

The column controller 218 may be coupled to the pixel array 210 by way of one or more conductors, such as column lines 222. Column controllers may sometimes be referred to as column control circuits, readout circuit, or column decoders. The column lines 222 may be used for reading out pixel signals from pixels 212 and for supplying bias currents and/or bias voltages to pixels 212. If desired, during pixel readout operations, a pixel row in the pixel array 210 may be selected using the row controller 216 and pixel signals generated by pixels 212 in that pixel row can be read out along the column lines 222. The column controller 218 may include sample-and-hold circuitry for sampling and temporarily storing pixel signals read out from the pixel array 210, amplifier circuitry, analog-to-digital conversion (ADC) circuitry, bias circuitry, column memory, latch circuitry for selectively enabling or disabling the column circuitry, or other circuitry that is coupled to one or more columns of pixels 212 in the pixel array 210 for operating pixels 212 and for reading out pixel signals from pixels 212. ADC circuitry in the column controller 218 may convert analog pixel values received from the pixel array 210 into corresponding digital image data. The column controller 218 may supply digital image data to the image sensor controller 214 and/or the imaging controller 108 (FIG. 1A) over, for example, the serial communication channel 202.

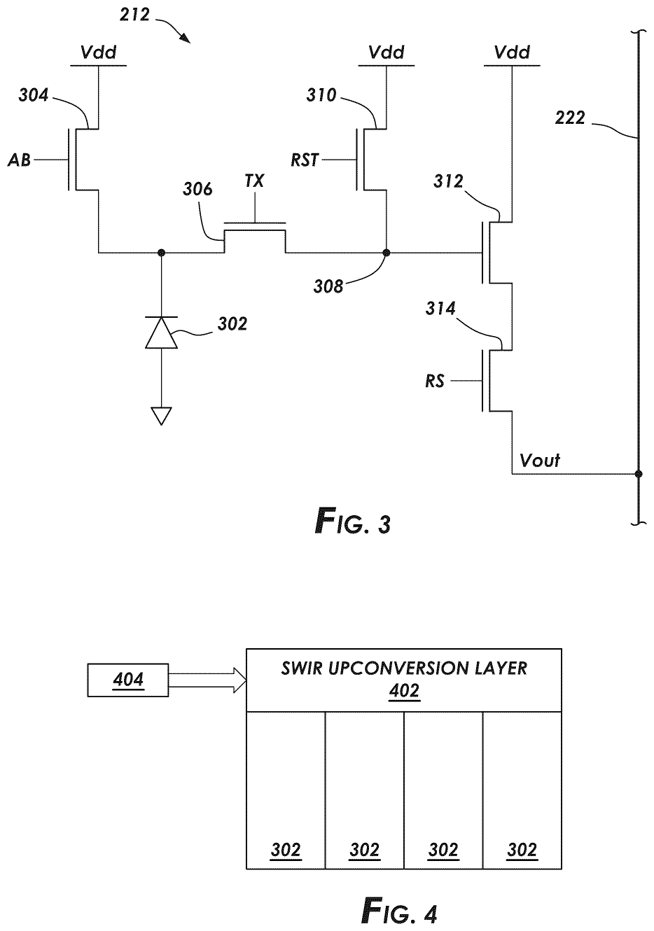

FIG. 3 is an electrical schematic of an example of one of the pixels 212 in the pixel array 210. The pixel 212 illustrated in FIG. 3 includes a silicon photodetector 302 in the example form of a photodiode, an anti-blooming transistor 304, a transfer transistor 306, a floating diffusion 308, a reset transistor 310, a source-follower transistor 312, and a row select transistor 314. The silicon photodetector 302 defines an anode coupled to ground or common, and a cathode coupled to the anti-blooming transistor 304 and the transfer transistor 306. The anti-blooming transistor 304 selectively connects the silicon photodetector 302 to a positive pixel power supply voltage, such as supply voltage Vdd. The transfer transistor 306 selectively connects the silicon photodetector 302 to the floating diffusion 308. The reset transistor 310 selectively connects the floating diffusion 308 to the positive pixel power supply voltage. The source-follower transistor 312 buffers a signal associated with charge stored in the floating diffusion 308. The row select transistor 314 selectively connects the source-follower transistor 312 to one of the column lines 222. In some implementations, some or all of the pixels 212 in the pixel array 210 may have the same components in the same configuration as the pixel 212 illustrated in FIG. 3. In other implementations, some or all of the pixels 212 in the pixel array 210 may have fewer components, additional components, or different components in different configurations than the pixel 212 illustrated in FIG. 3.

Before an image is acquired, the pixel array 210 is reset. For example, an anti-blooming control signal AB may be asserted to reset the pixel array 210. As illustrated in FIG. 3, the anti-blooming control signal AB is applied to the gate terminal of the anti-blooming transistor 304. Thus, the anti-blooming transistor 304 is made conductive when the anti-blooming control signal AB is asserted. Making the anti-blooming transistor 304 conductive resets the silicon photodetector 302 to a voltage equal or close to the supply voltage Vdd. Further, to reset the pixel array 210, a reset control signal RST may be asserted. As illustrated in FIG. 3, the reset control signal RST is applied to the gate terminal of the reset transistor 310. Thus, the reset transistor 310 is made conductive when the reset control signal RST is asserted. Making the reset transistor 310 conductive resets the floating diffusion 308 to a voltage equal or close to the supply voltage Vdd. After the floating diffusion 308 is reset, the reset control signal RST may be de-asserted to turn off the reset transistor 310.

After the pixel array 210 is reset, the silicon photodetector 302 gathers incoming light during an integration time. The silicon photodetector 302 converts the light to electrical charge. To arrange the pixel array 210 to be sensitive to light during the integration time, the anti-blooming control signal AB may be de-asserted to turn off the anti-blooming transistor 304. After (or during) the integration time, a transfer control signal TX may be asserted. As illustrated in FIG. 3, the transfer control signal TX is applied to the gate terminal of the transfer transistor 306. Thus, the transfer transistor 306 is made conductive when the transfer control signal TX is asserted. Making the transfer transistor 306 conductive transfers charge generated by the silicon photodetector 302 to the floating diffusion 308. After the charge is transferred to the floating diffusion 308, the transfer control signal TX may be de-asserted to turn off the transfer transistor 306. Next, a row select control signal RS may be asserted. As illustrated in FIG. 3, the row select control signal RS is applied to the gate terminal of the row select transistor 314. Thus, the row select transistor 314 is made conductive when the row select control signal RS is asserted. Making the row select transistor 314 conductive outputs an output signal Vout that is representative of the magnitude of charge stored in the floating diffusion 308. The output signal Vout is one example of a “pixel signal.” When the row select control signal RS is asserted, one of the column lines 222 can be used to route the output signal Vout to readout circuitry, such as the column controller 218 in FIG. 2. After the output signal Vout is output, the row select control signal RS may be de-asserted to turn off the row select transistor 314.

FIG. 4 is a cross-sectional side view of an example of a plurality of silicon photodetectors 302 arranged in an array. Imaging of short-wave infrared (SWIR) light with the silicon photodetectors 302 alone is difficult due to the very low absorption rates of the silicon photodetectors 302 for SWIR light. However, the silicon photodetectors 302 have high absorption rates for visible light. Thus, as illustrated in FIG. 4, a SWIR upconversion layer 402 is positioned in front of the silicon photodetectors 302. As described in more detail below, the SWIR upconversion layer 402 (an example of a “first upconversion layer”) emits visible light in response SWIR light when the electrons in the SWIR upconversion layer 402 are charged to a metastable state. In some implementations, the SWIR upconversion layer 402 includes erbium (Er) doped high Z bismuth oxychloride (BiOCl). As also illustrated in FIG. 4, a first energy emitter 404 is positioned and configured to charge the electrons in the SWIR upconversion layer 402 to a metastable state. The first energy emitter 404 may include a charge pump or a high energy light, such as a light-emitting diode. In the example shown, the silicon photodetectors 302 abut each other, but in other cases one or more additional layers, such as oxide layers or deep trench isolation (DTI) structures, may reside between them. Further, in the example shown, the SWIR upconversion layer 402 abuts the silicon photodetectors 302, but in other cases one or more additional layers or an empty space may reside between them.

In some implementations, different SWIR upconversion layers are positioned over different portions of the pixel array 210. For example, in a two-by-two cell, two diagonal pixels may have a first SWIR upconversion layer turned for a first SWIR wavelength range and the other two diagonal pixels may have a second upconversion layer tuned for a second SWIR wavelength range.

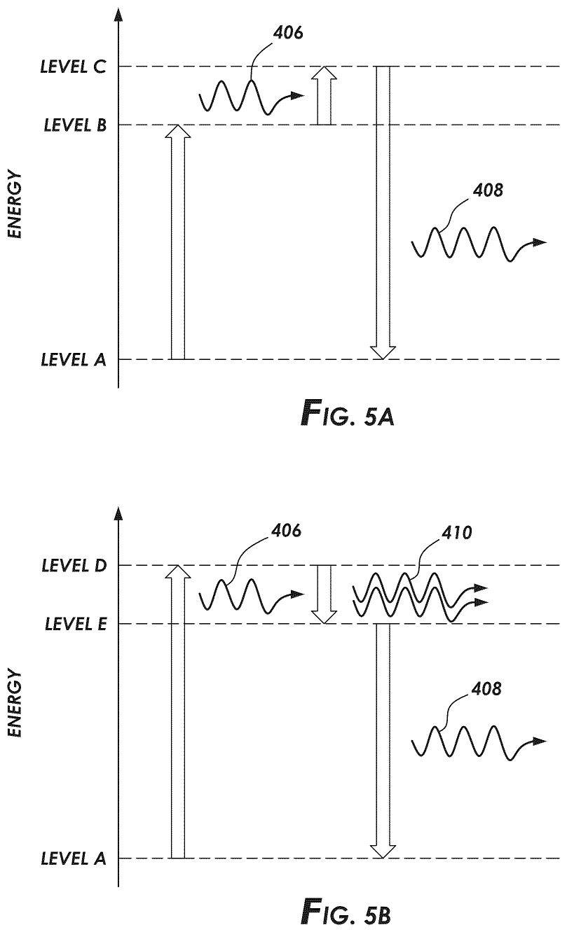

As described above, the first energy emitter 404 is configured to charge the electrons in the SWIR upconversion layer 402 to a metastable state. For example, as illustrated in FIG. 5A, the first energy emitter 404 may charge the electrons in the SWIR upconversion layer 402 from energy level A (for example, a ground state) to energy level B. Energy level B is stable and has a long excitation lifetime. In response to a SWIR photon 406, the SWIR upconversion layer 402 absorbs the SWIR photon 406, which increases the charge of the electrons in the SWIR upconversion layer 402 from energy level B to energy level C. Energy level C is non-stable and has a short excitation lifetime. At energy level C, the charge of the electrons in the SWIR upconversion layer 402 quickly decays from energy level C to energy level A, which results in emission of a high energy photon 408, such a visible light. Visible light is more detectable with the silicon photodetectors 302 than SWIR light.

As a further example, the first energy emitter 404 may charge the electrons in the SWIR upconversion layer 402 from energy level A to energy level D, as illustrated in FIG. 5B. Energy level D is stable and has a long excitation lifetime. In response to a SWIR photon 406, the SWIR upconversion layer 402 emits a low energy photon 410 which drops the SWIR upconversion layer 402 from energy level D to energy level E. Energy level E is non-stable and has a short excitation lifetime. At energy level E, the electrons in the SWIR upconversion layer 402 quickly decays from energy level E to energy level A, which results in emission of a high energy photon 408, again such as visible light.

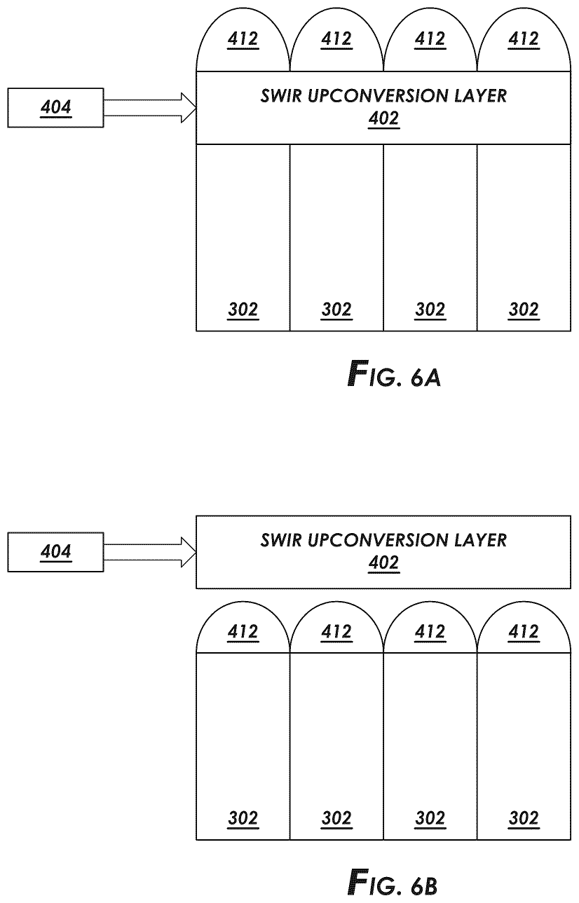

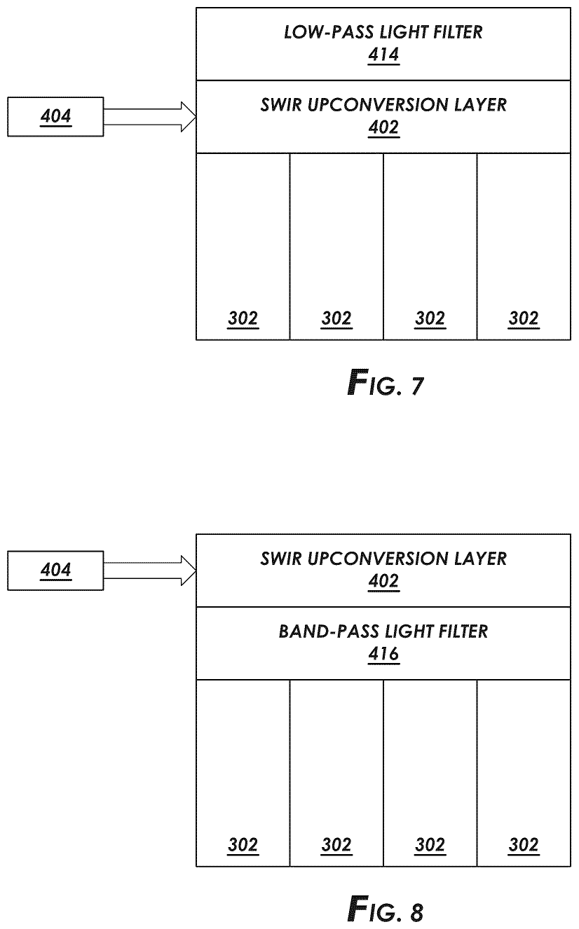

In some implementations, a plurality of microlenses 412 may be positioned above (or in front of) the SWIR upconversion layer 402 as illustrated in FIG. 6A. The microlenses 412 in FIG. 6A collimate SWIR light before the SWIR light enters the SWIR upconversion layer 402. In other implementations, the microlenses 412 may be positioned between the SWIR upconversion layer 402 and the silicon photodetectors 302 as illustrated in FIG. 6B. The microlenses 412 in FIG. 6B collimate visible light emitted by the SWIR upconversion layer 402 before the visible light enters the silicon photodetectors 302. Each of the microlenses 412 may be a convex lens or a spherical lens that collimates light. In some implementations, the microlenses 412 comprise inorganic materials such as silicon dioxide, silicon nitride, a combination thereof. In other implementations, the microlenses 412 may comprise organic materials.

In addition to the visible light emitted by the SWIR upconversion layer 402 in response to SWIR light in a scene, the silicon photodetectors 302 may detect other visible light present in the scene. To prevent the silicon photodetectors 302 from detecting visible light that is not caused by SWIR light, a low-pass light filter 414 may be positioned in front of the SWIR upconversion layer 402 to block high energy photons as illustrated in FIG. 7. The low-pass light filter 414 may block high energy photons from entering the SWIR upconversion layer 402. For example, to block visible light from entering the SWIR upconversion layer 402, the low-pass light filter 414 may block light with frequencies greater than about 400 terahertz. In this manner, the low-pass light filter 414 allows only low energy photons to pass through to the SWIR upconversion layer 402. The low-pass light filter 414 may include, for example, an interference filter or an absorptive filter. In some implementations, the low-pass filter 414 may be separate from the CMOS image sensor 106. In some implementations, the low-pass filter 414 includes a physical shutter that can be turned ON and OFF. When the physical shutter is turned OFF, the CMOS image sensor 106 may detect visible light. When the physical shutter is turned ON, the CMOS image sensor 106 may detect SWIR light.

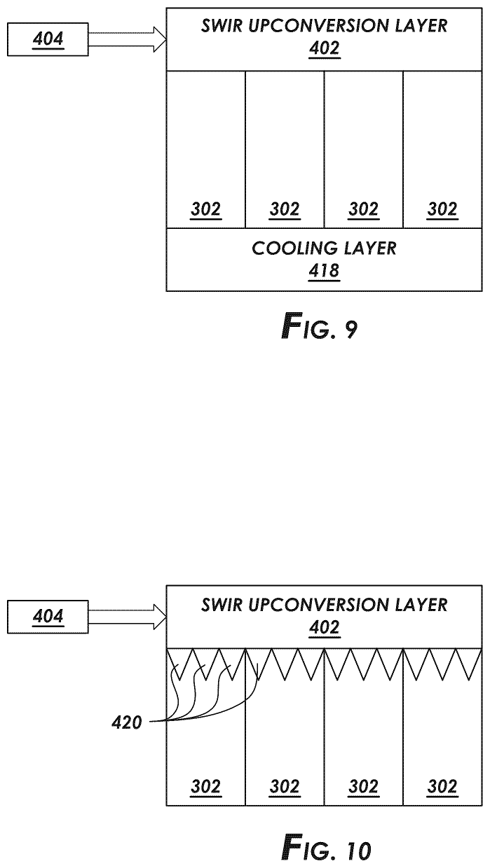

As described above, the SWIR upconversion layer 402 emits visible light in response SWIR light when the electrons in the SWIR upconversion layer 402 are charged to a metastable state. The wavelength of visible light emitted by the SWIR upconversion layer 402 varies based on the wavelength of SWIR light that enters the SWIR upconversion layer 402. For example, the SWIR upconversion layer 402 may emit 510 nanometer (nm) green light in response to 1,100 nm SWIR light, and also emit 560 nm green light in response to 1,600 nm SWIR light. The visible light emitted by the SWIR upconversion layer 402 in response to SWIR light is within a predetermined wavelength range that is set based on lowest and highest wavelengths of SWIR light that the SWIR upconversion layer 402 is configured to absorb. Thus, to prevent the silicon photodetectors 302 from detecting visible light that is not caused by SWIR light, a band-pass light filter 416 may be positioned between the silicon photodetectors 302 and the SWIR upconversion layer 402 as illustrated in FIG. 8. The band-pass light filter 416 may, for example, block light with wavelengths outside the predetermined wavelength range. In this manner, the band-pass light filter 416 allows only desired high energy photons emitted by the SWIR upconversion layer 402 in response to SWIR light to pass through for detection by the silicon photodetectors 302. The band-pass light filter 416 may include one or more interference filters, one or more color filters, or a combination thereof.

Heat produced during normal operation of the imaging system 100 may generate thermal noise. The thermal noise may have a low impact when detecting visible light because the thermal energy of the heat is much less than the photon energy of visible light. However, the thermal noise may a significant impact when detecting SWIR light because the thermal energy of the heat may be similar to the photon energy of SWIR light. For example, the thermal noise may induce electron transitions in the SWIR upconversion layer 402 that result in the SWIR upconversion layer 402 emitting photons of visible light. Thus, in some implementations, cooling may be used to reduce thermal noise in the CMOS image sensor. For example, a cooling layer 418 may be positioned on the back side of the silicon photodetectors 302 as illustrated in FIG. 9. The cooling layer 418 may include a heat sink, a heat dissipater, an active cooling device, or a combination thereof.

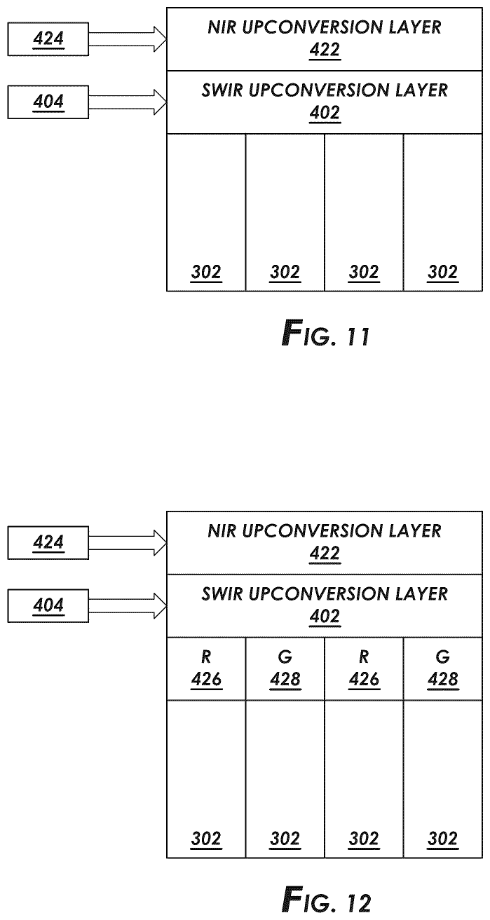

In some implementations, the silicon photodetectors 302 may include light scattering structures to increase the absorption rates of the silicon photodetectors 302. For example, each of the silicon photodetectors 302 illustrated in FIG. 10 includes a plurality of pyramid trenches 420 that disperse light evenly across the silicon photodetectors 302. The plurality of pyramid trenches 420 are one example of a light scattering structure. In some implementations, each of the silicon photodetectors 302 may include other light scattering structures such as vertical trenches.

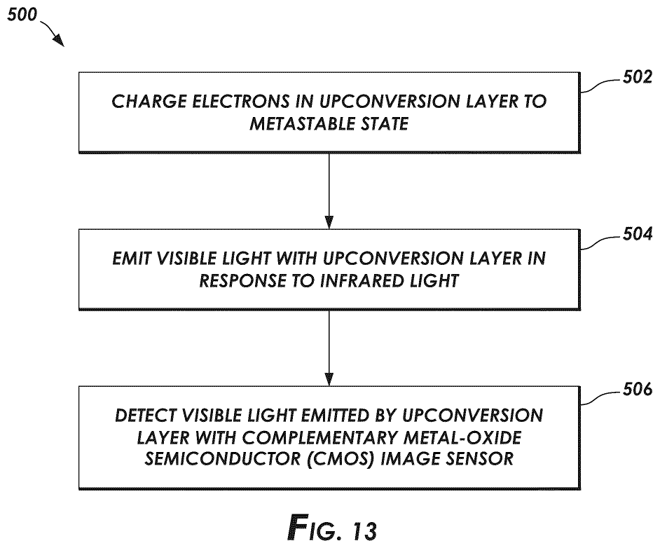

In addition to SWIR light, imaging of near infrared (NIR) light with the silicon photodetectors 302 is also difficult due to the low absorption rate of the silicon photodetectors 302 for NIR light. Thus, as illustrated in FIG. 11, a NIR upconversion layer 422 may be positioned in front of the silicon photodetectors 302. The NIR upconversion layer 422 (an example of a “second upconversion layer”) is configured to emit visible light in response to NIR light when the electrons in the NIR upconversion layer 422 are charged to a metastable state. As also illustrated in FIG. 11, a second energy emitter 424 is positioned and configured to charge the electrons in the NIR upconversion layer 422 to a metastable state. The second energy emitter 424 may include a charge pump or a high energy light, such as a light-emitting diode. The NIR upconversion layer 422 illustrated in FIG. 12 is positioned above the SWIR upconversion layer 402. However, in other implementations, the NIR upconversion layer 422 may be positioned between the SWIR upconversion layer 402 and the silicon photodetectors 302. In yet other implementations the NIR upconversion layer 422 may be positioned over the silicon photodetectors 302 without the SWIR upconversion layer 402.

In some implementations, the NIR upconversion layer 422 may be configured to emit a different color of visible light than the SWIR upconversion layer 402. For example, the NIR upconversion layer 422 may emit green light in response to NIR light and the SWIR upconversion layer 402 may emit red light in response to SWIR light. Color filter may be used to separately detect SWIR and NIR light. For example, as illustrated in FIG. 12, red color filters 426 are positioned between the SWIR upconversion layer 402 and two of the silicon photodetectors 302. The red color filters 426 are configured to pass visible light in the red wavelength range (such as wavelengths between about 590 nanometers and 690 nanometers) and block (or absorb) visible light outside of the red wavelength range. Further, as illustrated in FIG. 12, green color filters 428 are positioned between the SWIR upconversion layer 402 and the other two silicon photodetectors 302. The green color filters 428 are configured to pass visible light in the green wavelength range (such as wavelengths between about 500 nanometers and 590 nanometers) and block (or absorb) visible light outside of the green wavelength range.

FIG. 13 is a flow diagram of an example of a method 500 for imaging low energy photons in accordance with some implementations. For simplicity of explanation, the method 500 is depicted in FIG. 13 and described as a series of operations. However, the operations can occur in various orders and/or concurrently, and/or with other operations not presented and described herein. At block 502, electrons in an upconversion layer are charged to a metastable state. For example, the first energy emitter 404 may charge the electrons in the SWIR upconversion layer 402 from a ground state to a metastable state. As a further example, the second energy emitter 424 may charge the electrons in the NIR upconversion layer 422 from a ground state to a metastable state. At block 504, the upconversion layer emits visible light in response to infrared light. For example, SWIR light may increase (or decrease) the charge of the electrons in the SWIR upconversion layer 402 from the metastable state to a non-metastable state at which the charge of the electrons in the SWIR upconversion layer 402 quickly decays to the ground state, which results in emission of visible light. As a further example, NIR light may increase (or decrease) the charge of the electrons in the NIR upconversion layer 422 from the metastable state to a non-metastable state at which the charge of the electrons in the NIR upconversion layer 422 quickly decays to the ground state, which results in emission of visible light. At block 506, the visible light is detected with a CMOS image sensor. For example, the pixel array 210 may be arranged to be sensitive to visible light emitted by the SWIR upconversion layer 402 and/or the NIR upconversion layer 422 during an integration time. After the integration time, the image sensor controller 214 (or the imaging controller 108) may generate an image frame based on the visible light detected by the pixel array 210 during the integration time. In some implementations, the pixel array 210 is reset after the electrons in the SWIR upconversion layer 402 and/or the NIR upconversion layer 422 are charged to a metastable state.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various implementations of the present invention. Numerous variations and modifications will become apparent to those skilled in the art once the above disclosure is fully appreciated. It is intended that the following claims be interpreted to embrace all such variations and modifications.

What is claimed is:

1. An image sensor, comprising:
an upconversion layer configured to emit visible light in response to infrared light when electrons in the upconversion layer are charged to a metastable state;
an energy emitter configured to charge the electrons in the upconversion layer to the metastable state; and
a plurality of silicon photodetectors positioned behind the upconversion layer and configured to detect the visible light emitted by the upconversion layer.

2. The image sensor of claim 1, wherein the energy emitter includes a high energy light or an electronic charge pump.

3. The image sensor of claim 1, further comprising a plurality of microlenses positioned above the upconversion layer.

4. The image sensor of claim 1, further comprising a plurality of microlenses positioned between the upconversion layer and the plurality of silicon photodetectors.

5. The image sensor of claim 1, further comprising a low-pass light filter positioned in front of the upconversion layer and configured to block high energy photons.

6. The image sensor of claim 1, wherein the visible light emitted by the upconversion layer in response to the infrared light is inside a predetermined wavelength range, wherein the image sensor further comprises a band-pass light filter positioned between the upconversion layer and the plurality of silicon photodetectors, and wherein the band-pass light filter is configured to block light having wavelengths outside the predetermined wavelength range.

7. The image sensor of claim 1, wherein each of the plurality of silicon photodetectors include one or more light scattering structures.

8. The image sensor of claim 1, wherein the upconversion layer is a first upconversion layer, wherein the upconversion layer is further configured to emit a first visible light in response to short wave infrared (SWIR) light, wherein the metastable state is a first metastable state, wherein the energy emitter is a first energy emitter, and wherein the image sensor further comprises:
a second upconversion layer positioned in front of the plurality of silicon photodetectors and configured to emit a second visible light in response to near infrared (NIR) light when electrons in the second upconversion layer are charged to a second metastable state; and
a second energy emitter configured to charge the electrons in the second upconversion layer to the second metastable state.

9. An imaging system, comprising:
an upconversion layer configured to emit visible light in response to infrared light when electrons in the upconversion layer are charged to a metastable state;
a controller configured to charge the electrons in the upconversion layer to the metastable state; and
a complementary metal-oxide semiconductor (CMOS) image sensor configured to detect the visible light emitted by the upconversion layer.

10. The imaging system of claim 9, wherein the controller is further configured to:
reset a pixel array in the CMOS image sensor after the electrons in the upconversion layer are charged to the metastable state,
arrange the pixel array to be sensitive to the visible light emitted by the upconversion layer for an integration time, and
capture an image frame generated by the CMOS image sensor.

11. The imaging system of claim 9, further comprising a plurality of microlenses configured to collimate the infrared light before the infrared light enters the upconversion layer.

12. The imaging system of claim 9, further comprising a plurality of microlenses configured to collimate the visible light emitted by the upconversion layer before the visible light enters the CMOS image sensor.

13. The imaging system of claim 9, further comprising a low-pass light filter configured to block high energy photons from entering the upconversion layer.

14. The imaging system of claim 9, wherein the visible light emitted by the upconversion layer in response to the infrared light is inside a predetermined wavelength range, and wherein the image sensor further comprising a band-pass light filter configured to block light having wavelengths outside the predetermined wavelength range from entering the CMOS image sensor.

15. The imaging system of claim 9, further comprising a cooling layer configured to reduce thermal noise in the CMOS image sensor.

16. The imaging system of claim 9, wherein the upconversion layer is further configured to emit a first visible light inside a first predetermined wavelength range in response to short wave infrared (SWIR) light, wherein the upconversion layer is a first upconversion layer, wherein the metastable state is a first metastable state, wherein the imaging system further comprises a second upconversion layer configured to emit a second visible light inside a second predetermined wavelength range in response to near infrared (NIR) light when electrons in the second upconversion layer are charged to a second metastable state, and wherein the controller is further configured to charge the electrons in the second upconversion layer to the second metastable state.

17. The imaging system of claim 16, wherein the CMOS image sensor is further configured to:
block visible light with wavelengths outside the first predetermined wavelength range from entering at least a first portion of a pixel array in the CMOS image sensor, and
block visible light with wavelengths outside the second predetermined wavelength range from entering at least a second portion of the pixel array.

18. The imaging system of claim 9, wherein the imaging system is included in at least one selected from the group consisting of an automobile, a vehicle, a camera, a cellular telephone, a tablet computing, a webcam, a video camera, a video surveillance system, and a video gaming system.

19. A method for imaging low energy photons, the method comprising:
charging electrons in an upconversion layer to a metastable state;
emitting visible light with the upconversion layer in response to infrared light; and
detecting the visible light emitted by the upconversion layer with a complementary metal-oxide semiconductor (CMOS) image sensor.

20. The method of claim 19, further comprising:
resetting a pixel array in the CMOS image sensor after the electrons in the upconversion layer are charged to the metastable state;
arranging the pixel array to be sensitive to the visible light emitted by the upconversion layer for an integration time; and
capturing an image frame generated by the CMOS image sensor.
